(19) United States
(12) Patent Application Publication
(10) Pub. No.: US 2026/0351324 A1
(43) Pub. Date: Nov. 5, 2026

(54) MEMORY APPARATUS AND OPERATION METHOD THEREOF

(71) Applicant: Samsung Electronics Co., Ltd., Suwon-si (KR)

(72) Inventor: Jongho Kim, Suwon-si (KR)

(73) Assignee: Samsung Electronics Co., Ltd., Suwon-si (KR)

(21) Appl. No.: 19/467,675

(22) Filed: Feb. 2, 2026

(30) Foreign Application Priority Data
Apr. 30, 2025 (KR) 10-2025-0057069

(51) Int. Cl. G11C 16/34; G11C 16/08; G11C 16/10

(52) U.S. Cl. CPC G11C 16/3459; G11C 16/08; G11C 16/102

(57) ABSTRACT

Provided is an operation method of a memory apparatus, including programming a plurality of first memory cells connected to a first word line in strings connected to a first string select line (SSL), obtaining a first pass loop count corresponding to a first program state of the plurality of first memory cells which are programmed, programming a plurality of second memory cells connected to the first word line in a plurality of strings connected to a second SSL into the first program state, obtaining a second pass loop count corresponding to the first program state of the plurality of second memory cells which are programmed into the first program state, and deciding, based on the first pass loop count and the second pass loop count, whether a program of a plurality of memory cells connected to the first word line has failed.

### CROSS-REFERENCE TO RELATED APPLICATIONS

This present application claims priority to and the benefit under 35 U.S.C. § 119(a)-(d) of Korean Patent Application No. 10-2025-0057069, filed on Apr. 30, 2025, in the Korean Intellectual Property Office, the entire disclosure of which is incorporated herein by reference.

### FIELD

Example embodiments relate to a memory apparatus, and more specifically, to a memory apparatus for detecting a program error and an operation method thereof.

### BACKGROUND

A not AND (NAND) flash memory may be programmed in a method of sequentially applying a voltage to change a state when data is stored in a memory cell. A physical characteristic may vary for each memory cell, and a program response may differ depending on a manufacturing process or a degree of deterioration. Accordingly, memory cells may include a faulty memory cell, and an error correction code (ECC) may be adopted based on the faulty memory cell.

Uncorrectable error correction code (UECC) indicates an error in which stored data is in an uncorrectable state, and indicates an error of being unable to restore stored data even when a program is shown to have succeeded in a word line. The UECC may occur due to various causes such as a characteristic deviation between cells, electrical interference, a problem of timing of a peripheral circuit, a disagreement of a control signal and the like. Therefore, a method of analyzing and detecting a possibility of an occurrence of the UECC in advance may be required.

### SUMMARY

Aspects provide a memory apparatus which detects a program error occurring in a memory cell and an operation method thereof.

According to aspects, there is provided an operation method of a memory apparatus, including programming a plurality of first memory cells connected to a first word line in strings connected to a first string select line (SSL), obtaining a first pass loop count corresponding to a first program state of the plurality of first memory cells which are programmed, programming a plurality of second memory cells connected to the first word line in a plurality of strings connected to a second SSL in the first program state, obtaining a second pass loop count corresponding to the first program state of the plurality of second memory cells which are programmed in the first program state, and deciding, based on the first pass loop count and the second pass loop count, whether a program of a plurality of memory cells connected to the first word line has failed.

According to aspects, there is provided a memory apparatus including a cell array including a plurality of memory cells, a voltage generator providing a program voltage or a verify voltage to a word line of memory cells selected from the plurality of memory cells, and a control logic circuit configured to program a plurality of first memory cells of the plurality of memory cells connected to a first word line in strings connected to a first SSL, obtain a first pass loop count corresponding to a first program state of the plurality of first memory cells which are programmed, program a plurality of second memory cells among the plurality of memory cells connected to the first word line in a plurality of strings connected to a second SSL in the first program state, obtain a second pass loop count corresponding to the first program state of the plurality of second memory cells which are programmed in the first program state, and decide, based on the first pass loop count and the second pass loop count, whether a program of the plurality of memory cells connected to the first word line has failed.

According to aspects, there is provided an operation method of a memory apparatus, including performing a first program loop to a plurality of first strings which are connected to a first SSL and are in an erasure state, obtaining a first fail cell count of the plurality of first strings to which the first program loop is performed, performing a second program loop to a plurality of second strings which are connected to a second SSL and are in an erasure state, obtaining a second fail cell count of the plurality of second strings to which the second program loop is performed, and deciding, based on the first fail cell count and the second fail cell count, whether a program of a plurality of memory cells connected to the first SSL or the second SSL has failed.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 is a block diagram illustrating a memory apparatus according to example embodiments of the present disclosure;

FIG. 2 is a drawing that shows a cell array structure according to example embodiments of the present disclosure;

FIG. 3 is a block diagram illustrating an error detection circuit according to example embodiments of the present disclosure;

FIG. 4A, FIG. 4B, FIG. 4C, FIG. 4D, FIG. 4E, and FIG. 4F illustrate a loop count graph in a program state, which is programmed according to example embodiments of the present disclosure;

FIG. 5 illustrates a case of having discerned a program failure based on a maximum loop count;

FIG. 6A and FIG. 6B are flowcharts illustrating an error detection method of a memory apparatus according to example embodiments of the present disclosure;

FIG. 7 is a flowchart illustrating an error detection method of a memory apparatus according to example embodiments of the present disclosure;

FIG. 8A, FIG. 8B, and FIG. 8C illustrate a table which is updated by using pass loop counts and parameters in each program state of memory cells connected to a plurality of SSLs according to example embodiments of the present disclosure;

FIG. 9 is a flowchart illustrating a first loop error detection method of a memory apparatus according to example embodiments of the present disclosure;

FIG. 10A, FIG. 10B, and FIG. 10C are graphs illustrating a result of having performed a first loop program according to example embodiments of the present disclosure; and

FIG. 11 is a block diagram illustrating a memory system according to example embodiments of the present disclosure.

### DETAILED DESCRIPTION

In the present disclosure, a NAND-type flash memory apparatus will be used as an example of a non-volatile memory apparatus for explaining a characteristic and a function of the present disclosure. However, according to the descriptions herein, other advantages and functions of the present disclosure will be easily understood. For instance, a technology of the present disclosure may be used for a phase-change random access memory (PRAM), a magneto-resistive random access memory (MRAM), a resistive random access memory (ReRAM), a ferroelectric random access memory (FRAM), a not OR (NOR) flash memory and the like.

In the present disclosure, ‘program state’ may indicate a state of indicating whether all memory cells selected after a maximum program loop is applied are programmed. Pass of a program state may indicate that data is stored in a selected memory cell according to an application of a program cycle. Fail of a program state may indicate that data is not normally written in selected memory cells.

In the present disclosure, ‘pass loop count’ may indicate the number of program loops performed to reach a target state aimed by a selected memory cell. Each loop may be constituted with a cycle for identifying whether a threshold voltage of a cell has reached a target voltage range through a verify operation after a program voltage is applied. A pass loop count may indicate the number of loops performed until a cell selected with respect to a particular target state is decided as pass for the first time, and, as described hereinafter, a pass loop count may be used as an index for indicating a program characteristic of a memory cell or whether a defect exists thereat.

In the present disclosure, ‘fail cell count’ indicates the number of cells which have not satisfied a predetermined standard, and are detected by a read operation or a verify operation after programming among memory cells. A fail cell may be generated from a cell which has not reached a predetermined target state, or a cell outputting a value different from an estimated logic value during a read operation, and the number of fail bits may be utilized for evaluating a program quality of memory cells, or determining whether an abnormality exists at a particular area in a cell array. Further, a fail cell count may be used in place of or in parallel with a fail bit count.

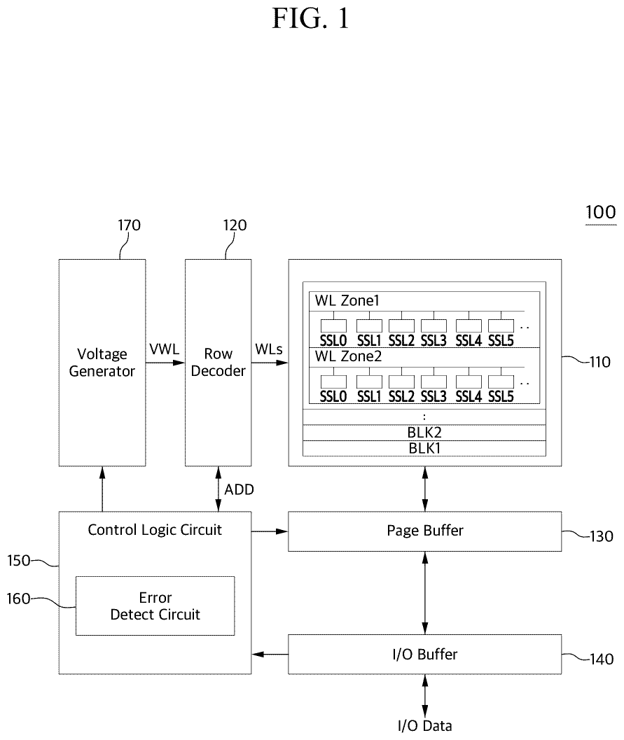

FIG. 1 is a block diagram illustrating a memory apparatus according to example embodiments of the present disclosure.

Referring to FIG. 1, a memory apparatus 100 may include a cell array 110, a row decoder 120, a page buffer 130, an input and output buffer 140, a control logic circuit 150, an error detection circuit 160 and a voltage generator 170.

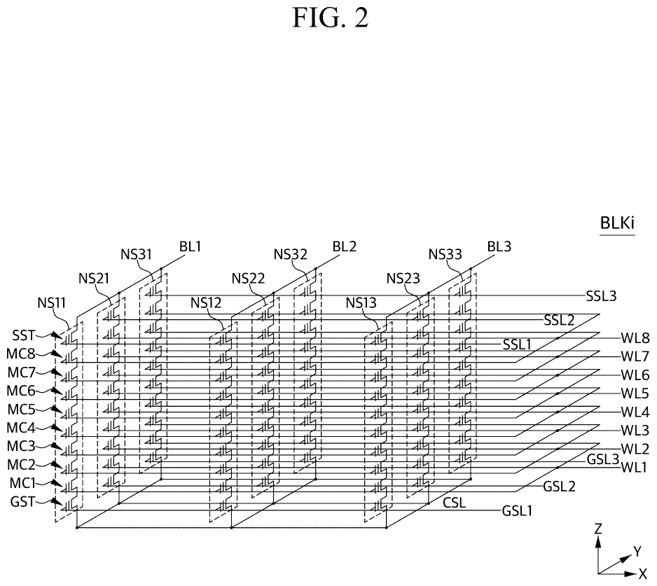

The cell array 110 may be connected to the row decoder 120 through word lines WLs. The cell array 110 may be connected to the row decoder 120 by select lines as described hereinafter with reference to FIG. 2. Further, the cell array 110 may be connected to the page buffer 130 through bit lines. The cell array 110 may include a plurality of cell strings, and the plurality of cell strings may constitute a memory block (e.g., BLK1 or BLK2). Here, a channel of each of cell strings may be formed in a vertical or horizontal direction. A memory cell included in the cell array 110 may be programmed by a voltage provided through a word line and a bit line.

According to example embodiments of the present disclosure, the cell array 110 may be provided in a three-dimensional memory array. The three-dimensional memory array may be monolithically formed at one or more physical levels of arrays of memory cells having an active area arranged on a silicon substrate and a circuit related to an operation of memory cells. A circuit related to an operation of memory cells may be located in a substrate or on a substrate. The term monolithic may indicate that layers of each level of a three-dimensional array are directly deposited on layers of a lower level of the three-dimensional array. In other words, the cell array 110 may have a vertical not AND (VNAND) structure.

A memory block may include a plurality of word lines, and each word line may be connected to a plurality of SSLs. For instance, as illustrated in FIG. 1, in a first word line zone (e.g., WL Zone1) corresponding to a first word line, cell strings may be connected to a plurality of SSLs (e.g., SSL0, SSL1, SSL2, SSL3, SSL4, SSL5 and the like). Also, in a second word line zone (e.g., WL Zone2) corresponding to a second word line, which is included in an identical block as that of the first word line zone (e.g., WL Zone1), cell strings may be connected to a plurality of SSLs (e.g., SSL0, SSL1, SSL2, SSL3, SSL4, SSL5 and the like). In the present disclosure, an SSL may refer to memory cells included in strings connected to an SSL.

In example embodiments, the row decoder 120 may select one of the word lines WLs of the cell array 110 in response to an address ADD. For instance, the row decoder 120 may select one of a plurality of memory blocks, and may select one of the word lines in the selected memory block. The row decoder 120 may apply a voltage to the selected word line based on a word line voltage VWL supplied from the voltage generator 170. During a write operation, the row decoder 120 may apply a writing voltage and a verify voltage to a selected word line, and may apply a pass voltage to a non-selected word line. During a read operation, the row decoder 120 may supply a selected read voltage to a selected word line, and a non-selected read voltage to a non-selected word line.

The page buffer 130 may operate as a write driver during a write operation, and may operate in a sensing amplifier during a read operation. During a write operation, the page buffer 130 may provide a voltage and/or a current corresponding to data to be written through a bit line to the cell array 110. During a read operation, the page buffer 130 may detect a voltage and/or a current of a bit line, in order to detect data stored in a selected memory cell. The page buffer 130 may latch the detected data to deliver the same to the input and output buffer 140.

The input and output buffer 140 may provide input and output data (may be referred to as written data) received from the outside during a write operation to the page buffer 130. The input and output buffer 140 may output data provided from the page buffer 130 during a read operation to the outside as input and output data. The input and output buffer 140 may deliver the address ADD or a command, received from the outside, to the control logic circuit 150 or the row decoder 120.

In example embodiments, the control logic circuit 150 may control the row decoder 120 and the voltage generator 170 in response to the delivered command. The control logic circuit 150 may control the voltage generator 170 and the row decoder 120 to program data provided from the outside in response to a writing command into selected memory cells. For instance, the control logic circuit 150 may control the row decoder 120 and the voltage generator 170 to program selected memory cells according to an incremental step pulse programming (ISPP) method. In the ISPP method, a program cycle may be performed to program selected memory cells (for instance, memory cells connected to a selected word line). A program cycle (or a program operation) is constituted with a plurality of program loops. In each of program loops, at least one program pulse and at least one verify pulse may be applied. A program pulse may be a pulse having a level of a program voltage, and a verify pulse may be a pulse having a level of a verify voltage. As a loop count increases, a level of a program voltage may increase in the ISPP.

In example embodiments, the error detection circuit 160 may, based on a pass loop count of first memory cells included in cell strings connected to a first SSL and a pass loop count of second memory cells included in cell strings connected to a second SSL among a plurality of memory cells connected to an identical word line, decide whether a program of the plurality of memory cells connected to the word line has failed. For instance, the error detection circuit 160 may obtain a first pass loop count corresponding to a first program state from memory cells connected to the first SSL and a second pass loop count corresponding to a second program state obtained from memory cells connected to the second SSL, and may compare the first pass loop count to the second pass loop count to decide whether the program of the plurality of memory cells connected to the word line has failed.

In example embodiments, the voltage generator 170 may generate the word line voltage VWL which is to be supplied to each of the word lines WLs according to control of the control logic circuit 150 and a voltage to be supplied to a bulk (for instance, a well region) at which memory cells are formed. The word line voltage VWL may include a program voltage, a pass voltage, a selected read voltage and a non-selected read voltage. The voltage generator 170 may generate a select line voltage provided to select lines in a read operation and a program operation. Further, the voltage generator 170 may generate a verify voltage according to control of the control logic circuit 150, and may provide the verify voltage to the row decoder 120.

In example embodiments, the memory apparatus 100 may detect a case in which a program state among a plurality of program states is completed with an abnormal pass loop count. Further, the memory apparatus 100 may output a detection result to the outside, and may detect uncorrectable error correction code error (UECC). In other words, even in a case in which a program state is pass, the memory apparatus 100 may detect the same as a program error to block the UECC.

FIG. 2 is a circuit diagram that shows a cell array structure according to example embodiments of the present disclosure.

Referring to FIG. 1 and FIG. 2, FIG. 2 simply illustrates a structure of a memory block (e.g., BLKi) constituting the cell array 110. A plurality of NAND strings (e.g., NS11, NS21, and NS31) may be arranged in rows and columns on a substrate. The plurality of NAND strings (e.g., NS11, NS21, and NS31) may be connected to a common source line CSL formed on or in a substrate. FIG. 2 illustrates that the common source line CSL is connected to a lower end of the plurality of NAND strings (e.g., NS11, NS21, and NS31) as an example, but it is sufficient that the common source line CSL is electrically connected to a lower end of cell strings (CS), and is not limited to being located at the lower end of the NAND strings (e.g., NS11, NS21, and NS31). For instance, the NAND strings (e.g., NS11, NS21, and NS31) are illustrated as being arranged by 3×3, but the memory block (e.g., BLKi) may include the smaller or larger number of NAND strings.

The NAND strings (e.g., NS11, NS21, and NS31) may be connected to a corresponding grounding select line among a plurality of grounding select lines (e.g., GSL1, GSL2, GSL3, and GSL4) and a corresponding string select line among a plurality of string select lines (e.g., SSL1, SSL2, and SSL3). The NAND strings may be connected to a corresponding bit line among a plurality of bit lines (e.g., BL1, BL2, and BL3).

The memory block (e.g., BLKi) may include at least one grounding select transistor GST at which a NAND string is connected to a corresponding grounding select line, a plurality of memory cells (e.g., MC1, MC2, MC3, MC4, MC5, MC6, MC7, and MC8) respectively connected to a plurality of word lines (e.g., WL1, WL2, WL3, WL4, WL5, WL6, WL7, and WL8), and string select transistors SST which are respectively connected to SSLs. In each cell string, the grounding select transistor GST, the memory cells (e.g., MC1, MC2, MC3, MC4, MC5, MC6, MC7, and MC8), and the string select transistors SST may be serially connected in a Z axis direction, and may be sequentially stacked in the Z axis direction.

Memory cells of the NAND strings (e.g., NS11, NS21, and NS31) which are located at an identical height (or order) from the grounding select transistor GST may be electrically and commonly connected. The memory cells of the NAND strings (e.g., NS11, NS21, and NS31) which are located at a different height (or order) from the grounding select transistor GST may be electrically separated. For instance, although FIG. 2 illustrates that memory cells of an identical height are connected to an identical word line, memory cells of an identical height may be directly connected at a plane of a height at which the memory cells are formed or may be indirectly connected to one another through another layer such as a metal layer.

Memory cells corresponding to a single string (or grounding) select line and a single word line may form a single page. A write operation and a read operation may be performed by a unit of each page. Each memory cell of each page may store two or more bits. Bits written in memory cells of each page may form logic pages.

In example embodiments, the memory block (e.g., BLKi) may be provided in a three-dimensional memory array. A three-dimensional memory array may be monolithically formed at one or more physical levels of arrays of the memory cells (e.g., MC1, MC2, MC3, MC4, MC5, MC6, MC7, and MC8) which have an active area which is arranged on a silicon substrate and a circuit related to an operation of the memory cells (e.g., MC1, MC2, MC3, MC4, MC5, MC6, MC7, and MC8). A circuit related to an operation of the memory cells (e.g., MC1, MC2, MC3, MC4, MC5, MC6, MC7, and MC8) may be located in a substrate or on a substrate. Being monolithically formed may indicate that layers of each level of a three-dimensional array are directly deposited on layers of a lower level of the three-dimensional array.

In example embodiments, a three-dimensional memory array may include the vertical NAND strings (e.g., NS11, NS21, and NS31) (or the cell strings) at which at least one memory cell is located on another memory cell by having a z-axis directivity. At least one memory cell may include a charge trapping layer. Each cell string may further include at least one select transistor located on the memory cells (e.g., MC1, MC2, MC3, MC4, MC5, MC6, MC7, and MC8). At least one select transistor may have a structure identical to the memory cells (e.g., MC1, MC2, MC3, MC4, MC5, MC6, MC7, and MC8).

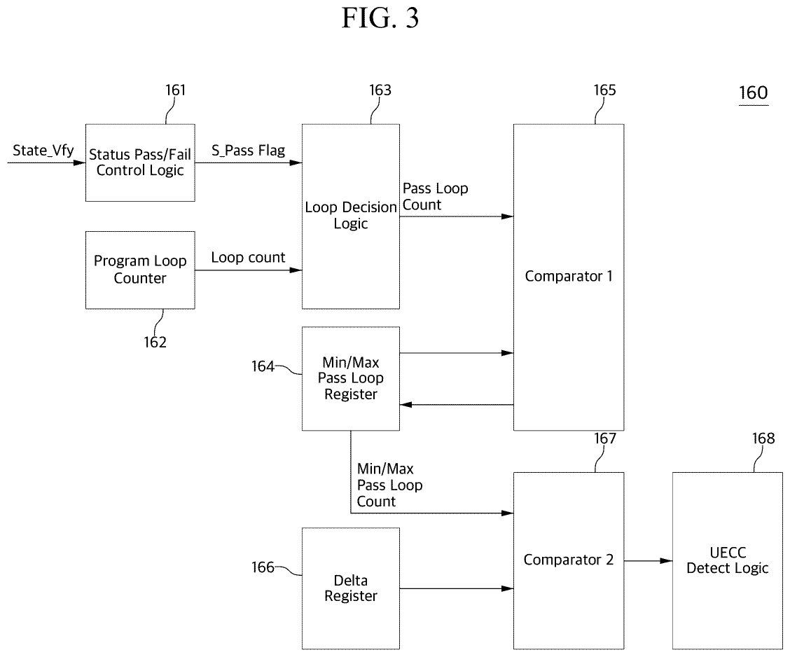

FIG. 3 is a block diagram illustrating an error detection circuit according to example embodiments of the present disclosure.

Referring to FIG. 3, the error detection circuit 160 according to example embodiments may include a state pass/fail control logic 161, a program loop counter 162, a loop determination logic 163, a minimum/maximum (Min/Max) pass loop register 164, a first comparator 165, a delta register 166, a second comparator 167, and an UECC detection logic 168. A configuration of the error detection circuit 160 is exemplary, and may be configured by including or modifying another configuration. For instance, the error detection circuit 160 may further include a subtractor and an e-fuse latch.

The state pass/fail control logic 161 may, in case that data is programmed, decide whether a program of each target state has succeeded. For instance, the state pass/fail control logic 161 may, based on a verify read result (e.g., State_Vfy), detect a point in time of pass of a program of each program state.

In example embodiments, when a program state is detected to be a program pass, the state pass/fail control logic 161 may output a state pass flag (e.g., S_Pass Flag). For instance, the state pass/fail control logic 161 may determine whether all cells selected by obtaining the verify read result (e.g., State_Vfy) are programmed in a program state (for instance, a P2). If all the selected memory cells are decided to have been programmed at a threshold voltage which is higher than a Vfy2, which is a verify read voltage of the second program state P2, the state pass/fail control logic 161 may deliver the state pass flag (e.g., S_Pass Flag) with respect to a program state to the loop determination logic 163.

In example embodiments, the program loop counter 162 may count a program loop, and may deliver a loop count to the loop determination logic 163. The program loop counter 162 sequentially increases a loop count in a program operation or cycle for programming the selected memory cells. The program loop counter 162 may deliver the loop count which sequentially increases from an initial loop to a final loop to the loop determination logic 163.

In example embodiments, the loop determination logic 163 may obtain the state pass flag (e.g., S_Pass flag) and the loop count. The loop determination logic 163 may generate a pass loop count based on the state pass flag (e.g., S_Pass flag) and the loop count. Here, the pass loop count may indicate a loop count at which a program of each program state is completed.

In example embodiments, the first comparator 165 may compare the pass loop count obtained from the loop determination logic 163 to a first parameter obtained from the Min/Max pass loop register 164, and may compare the pass loop count to a second parameter obtained from the Min/Max pass loop register 164. Here, the first parameter may indicate a maximum value of the pass loop count in a first program state of a plurality of SSLs, and the second parameter may indicate a minimum value of the pass loop count in the first program state of the plurality of SSLs. Therefore, the first parameter and the second parameter may respectively exist by the number of program states.

The first comparator 165 may compare the pass loop count to the first parameter in the first program state of the first SSL in order to deliver the pass loop count to the Min/Max pass loop register 164 in case that the pass loop count is greater than the first parameter. The Min/Max pass loop register 164 may update the first parameter with the delivered pass loop count.

Further, the pass loop count may be compared to the second parameter in the first program state of the first SSL in order for the pass loop count to be delivered to the Min/Max pass loop register 164 in case that the pass loop count is smaller than the second parameter. The Min/Max pass loop register 164 may update the second parameter with the delivered pass loop count.

In example embodiments, the Min/Max pass loop register 164 may store the first parameter and the second parameter for each of a plurality of program states, and may, based on the pass loop count in the first program state obtained from the first comparator 165, update the first parameter or the second parameter. The Min/Max pass loop register 164 may deliver the first parameter which is a maximum value of the pass loop count and the second parameter which is a minimum value of the pass loop count in the first program state to the second comparator 167.

In example embodiments, in case that memory cells connected to a second word line which is different from a first word line are programmed, the Min/Max pass loop register 164 may initialize the first parameter and the second parameter in each program state. Here, initializing may indicate initializing a register in which the first parameter and the second parameter in each program state are stored. In case that the first parameter and the second parameter of program states of the Min/Max pass loop register 164 are initialized, a pass loop parameter may be stored as the first parameter and the second parameter of each program state in each program state which is obtained.

In example embodiments, in case that memory cells are a quad-level cell (QLC), the first parameter and the second parameter of each program state may respectively exist as two pairs different from one another. In other words, in a case of an identical program state in a single word line, according to crossing of a program order or performing of a separating program of a plurality of rounds, the first parameter and the second parameter may be stored and updated in an independent manner to one another.

In example embodiments, the delta register 166 may store a threshold value. Here, the threshold value may indicate a allowable range of a difference between a maximum value and a minimum value of a pass loop count. Further, the delta register 166 may store a threshold value for each program state, and deliver a threshold value of a particular program state to the second comparator 167.

In example embodiments, a threshold value may be set for each program state. A threshold value may be set in an aspect of increasing as a loop count corresponding to a program state increases. As a program state increases, a pass loop count required for the corresponding program state may increase, in order for a greater threshold value to be set with respect to a great program state. Accordingly, a normal program operation may be prevented from being excessively decided as an error. For instance, in case that a program state exists from P1, P2, P3, P4, P5, P6, to P7, a threshold value may be set as 1, 1, 1, 1, 2, 2, 2 for each program state.

In example embodiments, a threshold value may be set according to the number of erasures of a word line. For instance, as for a threshold value, as a larger number of word lines are erased, a threshold value may be set to be lower. Because a memory cell connected to a word line becomes easier to deteriorate as the number of erasures of the word line increases, in order to detect a deteriorated memory cell at an early stage, a threshold value may be set to be lower as the number of erasures of the word line is greater.

In example embodiments, a threshold value may be set to vary depending on a type of memory cells. For instance, memory cells may be one of a single-level cell (SLC), a multi-level cell (MLC), a triple-level cell (TLC) and a QLC. In this case, a threshold value may be set to vary at the SLC, the MLC, the TLC and the QLC. For instance, a threshold value may be set to be the smallest at the SLC, and may be set to be greater in the order of the MLC, the TLC, and the QLC. A threshold value may be set according to the number of states stored for each memory cell, and, because, as the number of states increases, an interval between threshold voltages decreases and dispersion of a program increases, a threshold value may be set to gradually increase in the order of the SLC, the MLC, the TLC, and the QLC.

In example embodiments, the second comparator 167 may compare a threshold value of the first program state obtained from the delta register 166 and a difference between the first parameter and the second parameter of the first program state which are obtained from the Min/Max pass loop register 164. The second comparator 167 may include a subtractor, and may calculate a difference between the first parameter and the second parameter of the first program state. Further, the second comparator 167 may compare the threshold value of the first program state to the difference between the first parameter and the second parameter of the first program state to decide whether the difference exceeds the threshold value. The second comparator 167 may deliver whether the difference exceeds the threshold value to the UECC detection logic 168.

In example embodiments, in case that the difference between the first parameter and the second parameter of the first program state exceeds the threshold value of the first program state, the UECC detection logic 168 may decide that, although a program has passed, UECC has occurred at a memory cell connected to a word line. In example embodiments, the UECC detection logic 168 may decide that UECC has occurred in memory cells connected to a word line not only in memory cells connected to an SSL. The UECC detection logic 168 may output an error decision result.

In example embodiments, the memory apparatus 100 of FIG. 1 may perform a run-time bad block (RTBB) processing with respect to the corresponding word line according to the error decision result outputted from the UECC detection logic 168. Here, the RTBB may indicate a procedure of deciding a corresponding block as a faulty block and stopping use based on a program failure or an erasure failure which occur during an operation of the memory apparatus 100. For instance, in case that the RTBB processing is determined to be performed, the memory apparatus 100 may re-program corresponding data at a block which is different from a block which is processed as faulty.

FIG. 3 illustrates an on-chip structure in which the error detection circuit 160 is included in the memory apparatus 100, without being limited thereto. For instance, in an off-chip structure, the memory apparatus 100 may deliver a loop count for each program state by a command of a memory controller or an external device (for example, a host), and the memory controller may determine whether a program has failed by using the loop count for each program state, the first parameter and the second parameter.

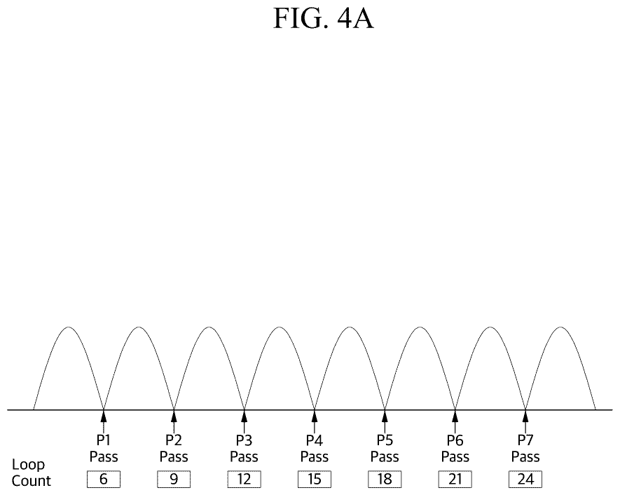

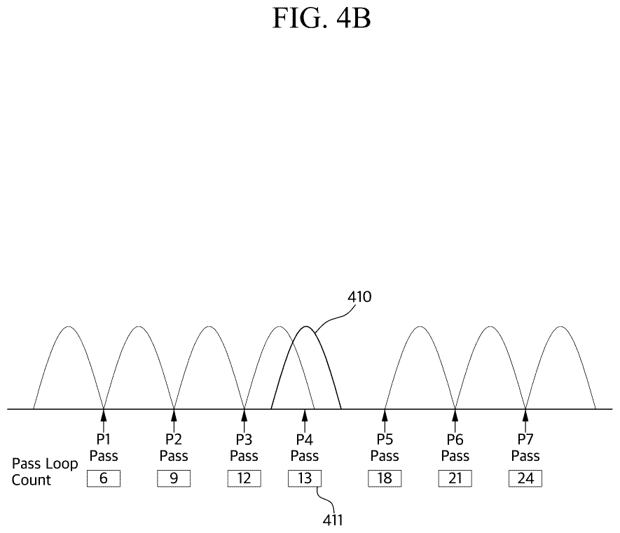

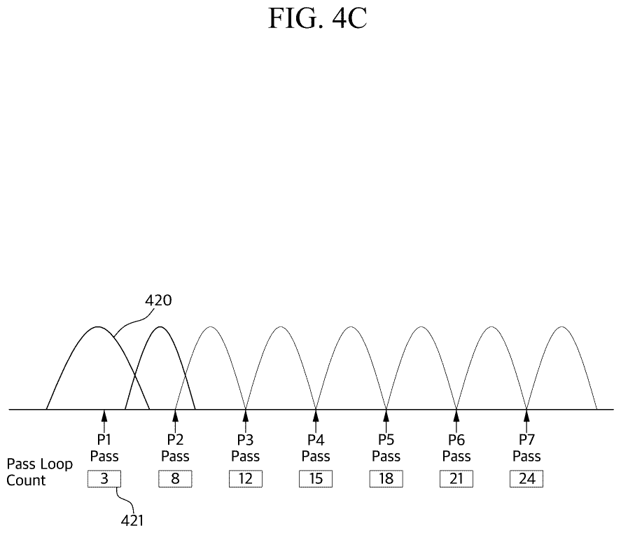

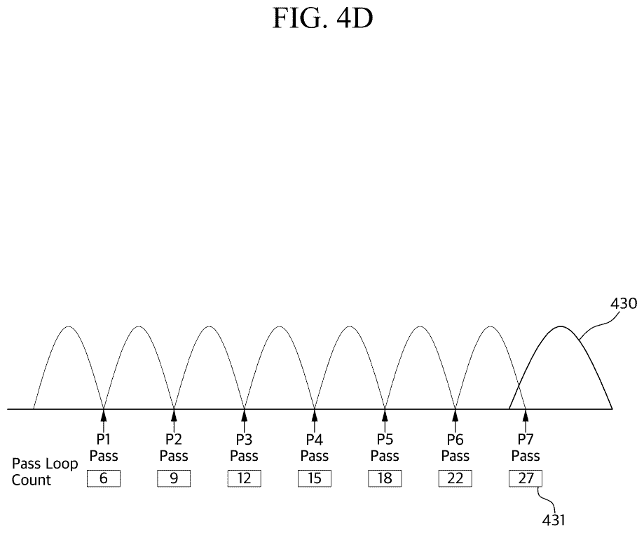

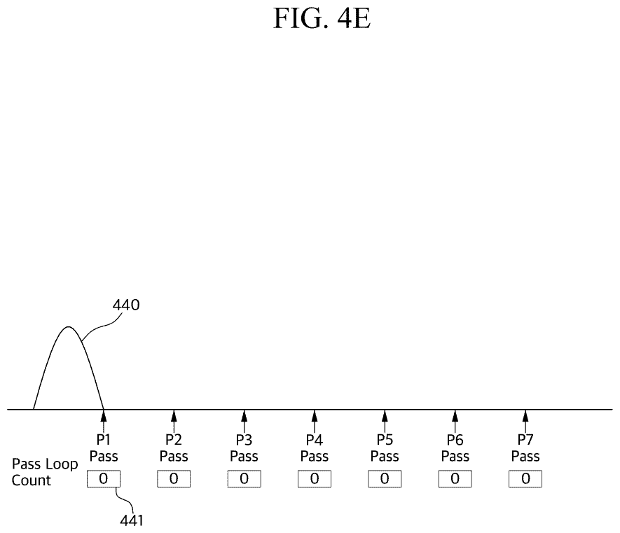

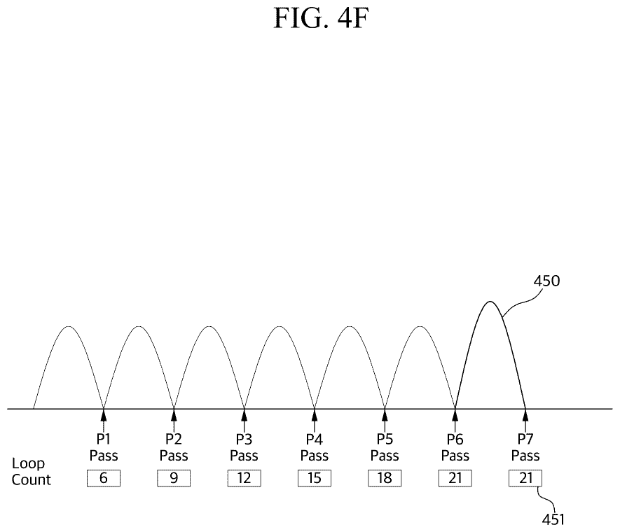

FIG. 4A to FIG. 4F illustrate loop count graphs in a program state which are programmed according to example embodiments of the present disclosure. For instance, FIG. 4A to FIG. 4F illustrate loop count graphs at a TLC storing 3 bits. In the graphs, a horizontal axis indicates the number of program loops, and a vertical axis indicates distribution of memory cells or the number of pass memory cells for reaching each program state.

Referring to FIG. 1 and FIG. 4A, a P1 state may pass at 6 of a loop count, and pass loop counts may respectively be 9, 12, 15, 18, 21, and 24 with respect to P2, P3, P4, P5, P6, and P7 states. The program may be performed in a method of applying a program voltage, which has increased by stages, to a memory cell, to decide whether each program state has passed verify.

In example embodiments, the memory apparatus 100 may have a maximum program loop count. Here, the maximum program loop count may indicate a maximum value of a loop count in the P7 which is a final program state after all program states have passed. For instance, in case that a maximum program loop count is 30 and the P7, which is the final program state, is unable to pass within 30, a corresponding memory cell may be decided to be a program failure in order for a program state to be decided as fail. In a case of FIG. 4A, because, in the P7, which is the final program state, the pass loop count is 24, programming is normally performed without an error, and programming may be normally performed also in another program state.

Referring to FIG. 1 and FIG. 4B, the P1 state may pass (P1 Pass) at 6 of a loop count, and pass loop counts may respectively be 9, 12, 13, 18, 21, and 24 with respect to the P2, P3, P4, P5, P6, and P7 states. In the P7 state, the final pass loop count is 24 which is smaller than 30 which is a maximum program loop count, in order for a program state to be finished as pass.

In the P4 state, due to at least one of various factors, such as an error of a peripheral circuit, a verify shift or a state missing may occur, and, as illustrated in FIG. 4B, a dispersion 410 corresponding to the P4 state may be moved from a normal location to a left side, wherein a pass loop count 411 may be 13. In this case, although UECC has occurred in the P4 state, an entire program state may be finished as pass, in order for corresponding data to be missing.

Referring to FIG. 1 and FIG. 4C, a pass loop count 421 in the P1 state may be 3, and pass loop counts may respectively be 8, 12, 15, 18, 21, and 24 with respect to the P2, P3, P4, P5, P6, and P7 states. In the P7 state, a final pass loop count is 24 which is smaller than 30 which is a maximum program loop count, in order for a program state to be finished as pass.

In a case of programming a word line adjacent to a programmed word line, a threshold voltage of memory cells has already increased at an initial stage of a program, in order for a dispersion 420 to be modified. In this case, as for a corresponding SSL, because the threshold voltage of the memory cell has already increased at the initial stage of the program, a program loop may be impossible to be normally performed. Although UECC has occurred in the P1 state, an entire program state may be finished as pass, in order for corresponding data to be missing.

Referring to FIG. 1 and FIG. 4D, the P1 state may pass at 6 of a loop count, and pass loop counts may respectively be 9, 12, 15, 18, 22, and 27 with respect to the P2, P3, P4, P5, P6, and P7 states. Here, a dispersion 430 in the P7 state may expand compared to a normal dispersion of FIG. 4A, and a pass loop count 431 in the P7 state may increase to 27, in order for UECC to occur in a corresponding SSL due to dispersion expansion in the P7 state, and, in case that another SSL is programmed in an identical word line or another SSL is programmed in another word line afterwards, UECC may occur. For instance, a pass loop count 231 in the P7 state has increased to 27 in order for an abnormality to begin to occur at a program, but, because the pass loop count 431 in the P7 state is 27 and is smaller than 30 which is a maximum value of a pass loop count, an entire program state may be finished as pass, and afterwards, in case that another SSL is programmed in an identical word line or another SSL is programmed in another word line, UECC occurs, in order for data in the P7 state, which is previously programmed, to be missing. Further, in case that UECC has occurred, previously programmed data may be missing along with the same. Referring to FIG. 1 and FIG. 4E, a pass loop count of all program states may be 0. Due to malfunction of a program state, it may be identified that a program has passed in a state in which verify is not performed although the program has not been performed. In this case, only a first dispersion 440 exists, and the pass loop count 411 in the P1 state may be 0. Therefore, although UECC has occurred, an entire program state may be finished as pass, in order for corresponding data to be missing.

Referring to FIG. 1 and FIG. 4F, the P1 state may pass at 6 of a loop count, and pass loop counts may respectively be 9, 12, 15, 18, 21, and 21 with respect to the P2, P3, P4, P5, P6, and P7 states. In the P6 state, in case that, although a program loop is completed by programming a memory cell with a dispersion 450 of a greater number, the memory cell is decided as pass despite not having reached a verify standard, the P7 state is not performed, and a pass loop count 451 may have 21 which is an identical value to a pass loop count in the P6 state. In this case, because a part of a logic value of the selected memory cell passes without being stored, an error may occur at a point in time of reading, in order for an entire program state to be finished as pass even though UECC has occurred, in order for corresponding data to be missing.

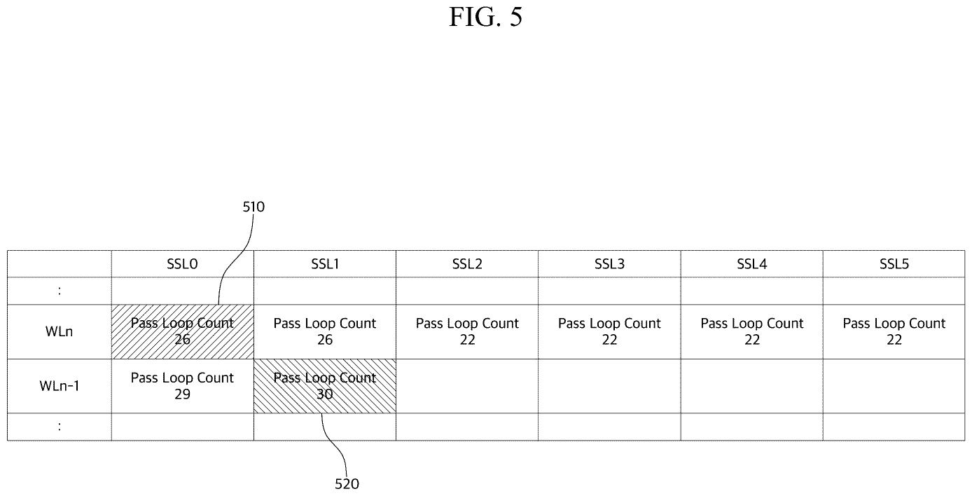

FIG. 5 illustrates a case of having discerned a program failure based on a maximum loop count.

Referring to FIG. 1 and FIG. 5, the memory apparatus 100 may set a maximum value of a pass loop count as 29, and memory cells connected to an nth word line WLn may be programmed, and then memory cells connected to an n-1th word line WLn-1 may be programmed. For instance, even in a case in which an abnormality has occurred in memory cells included in cell strings connected to an SSL0 510 among memory cells connected to the nth word line WLn, the memory apparatus 100 may decide that a program has passed with a final pass loop count being 26. Next, because memory cells included in cell strings connected to an SSL1 520 among memory cells connected to the n-1th word line WLn-1 have 30 as a final pass loop count, which exceeds 29 which is a maximum value of a pass loop count, the n-1th word line WLn-1 may undergo the RTBB processing. In case that the n-1th word line WLn-1 undergoes the RTBB processing, data of the nth word line WLn may be missing, in order for UECC to occur.

A progressive word line failure may occur because a word line which is to be programmed later may affect another word line which is previously programmed, in order for data of the another word line which is previously programmed to be missing. Therefore, the memory apparatus 100 according to example embodiments may detect a word line failure in advance based on a difference between pass loop counts among SSLs within an identical word line.

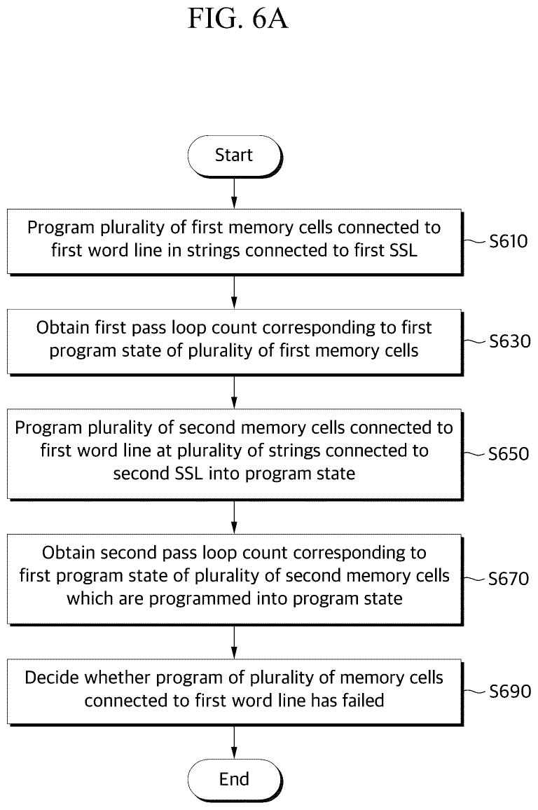

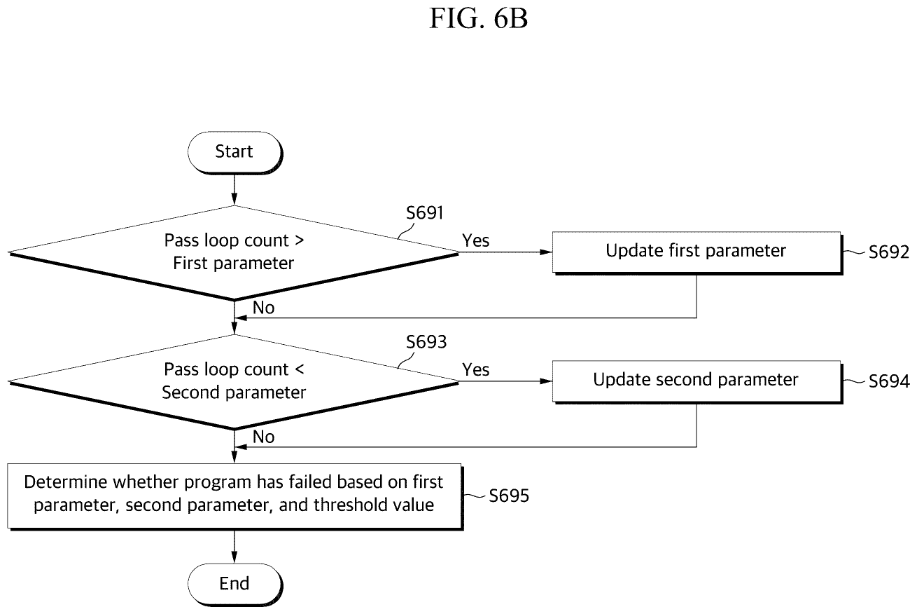

FIG. 6A is a flowchart illustrating an error detection method of a memory apparatus according to example embodiments of the present disclosure.

Referring to FIG. 1 and FIG. 6A, in operation S610, the memory apparatus 100 according to example embodiments may program a plurality of first memory cells connected to a first word line in strings connected to a first SSL. For instance, a plurality of memory cells included in the strings connected to the first SSL among a plurality of strings of the memory apparatus 100 may be selected. The plurality of memory cells which are selected may be programmed in a first program state (for instance, the P1 state) by an identical word line. In this case, each memory cell may repeatedly perform a program loop until reaching a threshold voltage range corresponding to the first program state.

In operation S630, the memory apparatus 100 according to example embodiments may obtain a first pass loop count corresponding to the first program state of the plurality of first memory cells. The memory apparatus 100 according to example embodiments may obtain the first pass loop count and calculate a program loop count until reaching the first program state with respect to each of the plurality of first memory cells.

In operation S650, the memory apparatus 100 according to example embodiments may program a plurality of second memory cells connected to the first word line in a plurality of strings connected to a second SSL into the first program state. For instance, the memory apparatus 100 may select a plurality of memory cells included in strings connected to the second SSL among the plurality of strings. The plurality of memory cells which are selected may be programmed in the first program state (for instance, the P1 state) by an identical word line. In this case, each memory cell may repeatedly perform a program loop until reaching a threshold voltage range corresponding to the first program state. In example embodiments, the second SSL and the first SSL may be adjacent to one another.

In operation S670, the memory apparatus 100 according to example embodiments may obtain a second pass loop count corresponding to the first program state of the plurality of second memory cells which are programmed in the first program state. The memory apparatus 100 according to example embodiments may obtain the second pass loop count and calculate a program loop count until reaching the first program state with respect to each of the plurality of second memory cells.

In operation S690, the memory apparatus 100 according to example embodiments may decide whether a program of the plurality of memory cells connected to the first word line has failed. The memory apparatus 100 may, based on the first pass loop count and the second pass loop count, decide whether the program of the plurality of memory cells connected to the first word line has failed.

For instance, the memory apparatus 100 may store the first parameter and the second parameter of the Min/Max pass loop register 164 in FIG. 2 as the first pass loop count, and may update the first parameter and the second parameter which are stored based on the second pass loop count. The memory apparatus 100 may compare a difference between the first parameter and the second parameter to a threshold value stored in the delta register 166 of FIG. 2 to determine whether the program of the plurality of memory cells connected to the first word line has failed.

FIG. 6B is a flowchart illustrating an error detection method of a memory apparatus according to example embodiments of the present disclosure. In example embodiments, operations (e.g., S691, S692, S693, S694, and S695) of FIG. 6B may be included in operation S690 of FIG. 6A.

Referring to FIG. 1 and FIG. 6B, in operation S691, the memory apparatus 100 according to example embodiments may decide whether the second pass loop count with respect to the second SSL is greater than the first parameter stored in a register in the first program state. In case that the second pass loop count is greater than the first parameter in the first program state (Yes in S691), in operation S692, the memory apparatus 100 according to example embodiments may update the first parameter stored in the register to a value of the second pass loop count in the first program state.

In case that the second pass loop count is smaller than the first parameter in the first program state (No in S691), in operation S693, the memory apparatus 100 according to example embodiments may decide whether the second pass loop count with respect to the second SSL is smaller than the second parameter stored in the register in the first program state. In case that the second pass loop count is smaller than the second parameter in the first program state (Yes in S693), in operation S694, the memory apparatus 100 according to example embodiments may update the second parameter stored in the register to the value of the second pass loop count in the first program state.

In case that the second pass loop count is greater than the second parameter in the first program state (No in S693), in operation S695, the memory apparatus 100 according to example embodiments may determine whether a program has failed based on the first parameter, the second parameter, and the threshold value. For instance, the memory apparatus 100 may determine that, in case that a difference between the updated first parameter and the updated second parameter is equal to or greater than the threshold value, the program of the plurality of memory cells connected to the first word line has failed.

In example embodiments, the threshold value may be set for each program state. The threshold value may be set in an aspect of increasing as a program state increases. As a program state increases, a pass loop count required for the corresponding program state may increase, in order for a greater threshold value to be set with respect to a great program state. Accordingly, a normal program operation may be prevented from being excessively decided as an error.

In example embodiments, the threshold value may be set according to the number of erasures of a word line. For instance, as for the threshold value, as a larger number of word lines are erased, the threshold value may be set to be lower. Because a memory cell connected to a word line becomes easier to deteriorate as the number of erasures of the word line increases, in order to detect a deteriorated memory cell at an initial stage, the threshold value may be set to be lower as the number of erasures of a word line is great.

In example embodiments, the threshold value may be set to vary depending on a type of memory cells. For instance, memory cells may be one of an SLC, an MLC, a TLC and a QLC. In this case, the threshold value may be set to vary at the SLC, the MLC, the TLC and the QLC.

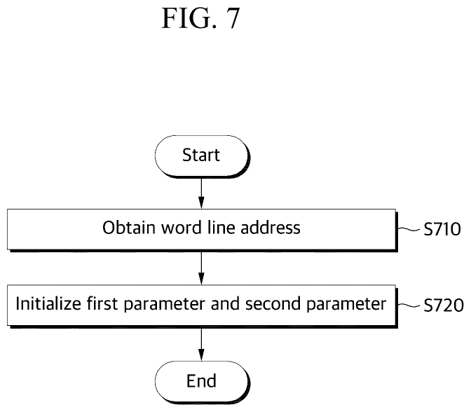

FIG. 7 is a flowchart illustrating an error detection method of a memory apparatus according to example embodiments of the present disclosure. Operation S710 and operation S720 of FIG. 7 may be performed before operation S610 of FIG. 6.

Referring to FIG. 1 and FIG. 7, in operation S710, the memory apparatus 100 may obtain a word line address. The memory apparatus 100 may obtain an address of a second word line which is different from the first word line. For instance, in case that a program is completed at the first word line, the address of the second word line may be received by the memory apparatus 100 through an internal address decoder or an external interface for a program of the second word line. An obtained address of a word line may be utilized as a standard for initializing a parameter used for a comparison operation of pass loop counts among SSLs.

In operation S720, the memory apparatus 100 according to example embodiments may initialize the first parameter and the second parameter. In case that a word line for programming changes, the memory apparatus 100 may initialize parameters for each program state which was used in a previous word line. The first parameter may indicate a maximum pass loop count for each program state, and the second parameter may indicate a minimum pass loop count for each program state. The first parameter and the second parameter may be initialized by the memory apparatus 100 initializing the register. Before programming memory cells connected to the second word line, the memory apparatus 100 may reset parameters for each program state at an initial value or set the same at a particular reference value.

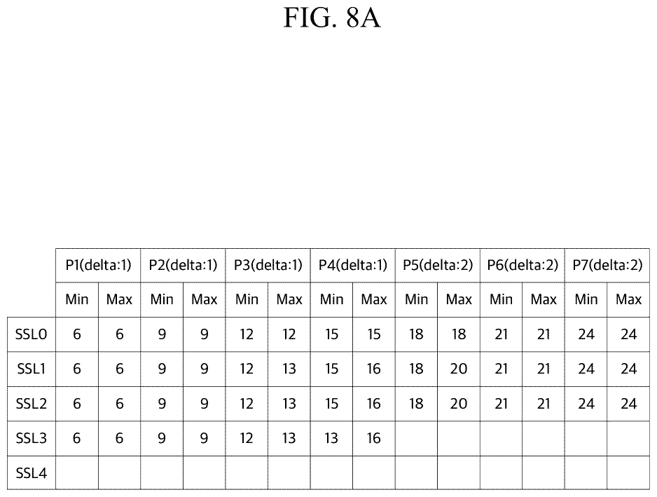

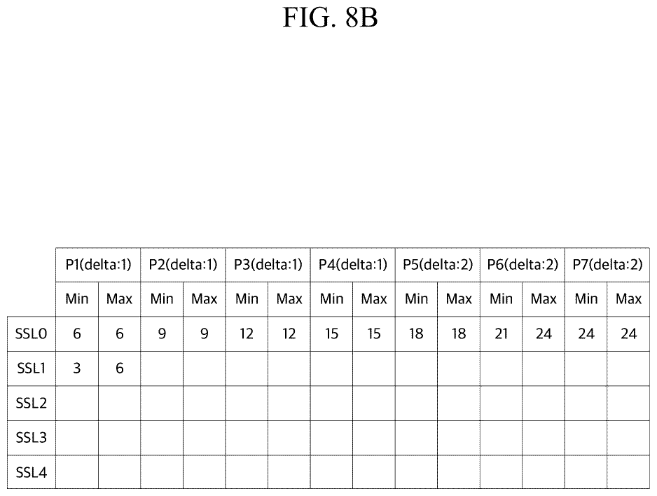

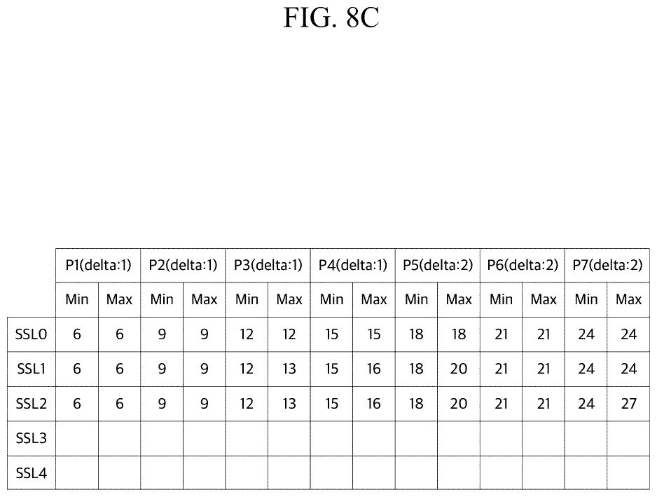

FIG. 8A illustrates a table which is updated by using pass loop counts and parameters in each program state of memory cells connected to a plurality of SSLs according to example embodiments of the present disclosure. By using the table of FIG. 8A, in case that an error has occurred in the P4 state of FIG. 4B, the error which has occurred in the P4 may be detected.

Referring to FIG. 4B and FIG. 8A, the first word line may be connected to the SSL0, the SSL1, the SSL2, and the SSL3, and the threshold value may be set at 1 in the P1, P2, P3, and P4 states, and may be set at 2 in the P5, P6, and P7 states. First, in a case of programming a memory cell connected to the SSL0, pass loop counts may respectively be 6, 9, 12, 15, 18, 21, and 24 in the P1, P2, P3, P4, P5, P6, and P7 states, and in each program state, a pass loop count may be stored in the first parameter (e.g., Max) and the second parameter (e.g., Min).

In case that a program with respect to the memory cell connected to the SSL0 is completed to the P7 state, a program with respect to a memory cell connected to the SSL1 may be performed. In this case, pass loop counts may respectively be 6, 9, 13, 16, 20, 21, and 24 in the P1, P2, P3, P4, P5, P6, and P7 states, and the first parameter (e.g., Max) and the second parameter (e.g., Min) may be updated after the pass loop counts are compared to the first parameter (e.g., Max) and the second parameter (e.g., Min) for each program state stored in the SSL0. In the SSL1, the pass loop count in the P3 state is 13, and the first parameter is 12, in order for the memory apparatus 100 to update the first parameter to 13. In the same method, in the SSL1, the pass loop count in the P4 state is 16, and the first parameter is 15, in order for the memory apparatus 100 to update the first parameter to 16. Because a difference between the first parameter and the second parameter in the P3 state and the P4 state is 1 and does not exceed 1 which is a threshold value (delta), the memory apparatus 100 may decide that a program has succeeded in the P3 state and the P4 state. Also, in the P5 state, in the same method, a program may be decided to have succeeded.

In case that, in the same method, a program of a memory cell connected to the SSL2 is decided to have succeeded, and a memory cell connected to the SSL3 is programmed, pass loop counts may respectively be 6, 9, 12, and 13 in the P1, P2, P3, and P4 states. Because the pass loop count 411 is 13 in the P4 state, 15 which is stored as the second parameter (e.g., Min) may be updated to 13, and, because a difference between the first parameter (e.g., Max) and the second parameter (e.g., Min) is 3, the corresponding difference exceeds 1 which is the threshold value (delta). Therefore, the memory apparatus 100 may decide that a program has failed in the P4 state, and accordingly, may decide that a program with respect to the memory cells connected to the SSL0, the SSL1, the SSL2, and the SSL3 included in an identical word line has also failed. For instance, the memory apparatus 100 may detect UECC which has occurred in the P4 state to perform the RTBB processing with respect to all memory cells connected to a word line.

FIG. 8B illustrates a table which is updated by using pass loop counts and parameters in each program state of memory cells connected to a plurality of SSLs according to example embodiments of the present disclosure. By using the table of FIG. 8B, in case that an error has occurred in the P1 state of FIG. 4C, the error which has occurred in the P1 may be detected. Identical or duplicate descriptions to descriptions in FIG. 8A will be omitted.

Referring to FIG. 4C and FIG. 8B, the memory cells connected to the SSL0 may be decided to have been successfully programmed in all program states. In case that the first parameter and the second parameter are stored for each program state of the SSL0, and that 3 is produced as the pass loop count 421 in the P1 state by programming the memory cells connected to the SSL1, the second parameter (e.g., Min) may be updated from 6 to 3. Because, in the P1 state, a difference between the first parameter (e.g., Max) and the second parameter (e.g., Min) is 3, which is greater than 1 which is the threshold value (delta), the memory apparatus 100 may decide that a program has failed in the P1 state, and may process that a program has failed with respect to all the memory cells connected to the SSL0 and the SSL1. In other words, the memory apparatus 100 may detect UECC which has occurred in the P1 state to perform the RTBB processing with respect to memory cells connected to a corresponding word line.

FIG. 8C illustrates a table which is updated by using pass loop counts and parameters in each program state of memory cells connected to a plurality of SSLs according to example embodiments of the present disclosure. By using the table of FIG. 8C, in case that an error has occurred in the P7 state of FIG. 4D, the error which has occurred at the P7 may be detected. Identical or duplicate descriptions to descriptions in FIG. 8A will be omitted.

After the memory cells connected to the SSL0 and the SSL1 are programmed, the first parameter (e.g., Max) and the second parameter (e.g., Min) may be updated and stored for each program state. Next, the program with respect to the memory cell connected to the SSL2 may be performed. In this case, pass loop counts may respectively be 6, 9, 13, 16, 19, 21, and 24 in the P1, P2, P3, P4, P5, P6, and P7 states, and the memory apparatus 100 may, based on the pass loop count of the SSL2 in the P1 state to the P6 state, update the first parameter (e.g., Max) and the second parameter (e.g., Min). Further, because a difference between the first parameter (e.g., Max) and the second parameter (e.g., Min) does not exceed the threshold value (delta) in the P1 state to the P6 state, the memory apparatus 100 may decide a program success in each program state. Because, in a case of the P7 state, the pass loop count is 27, the first parameter (e.g., Max) may be updated from 24 to 27, and, because a difference from the second parameter (e.g., Min) is 3, the same exceeds 2 which is the threshold value (delta). Therefore, the memory apparatus 100 may decide that a program has failed in the P7 state, and accordingly, may determine that a program with respect to the memory cells connected to the SSL0, the SSL1, and the SSL2 included in an identical word line has also failed. In other words, the memory apparatus 100 may detect UECC which has occurred in the P7 state to perform the RTBB processing with respect to memory cells connected to a word line.

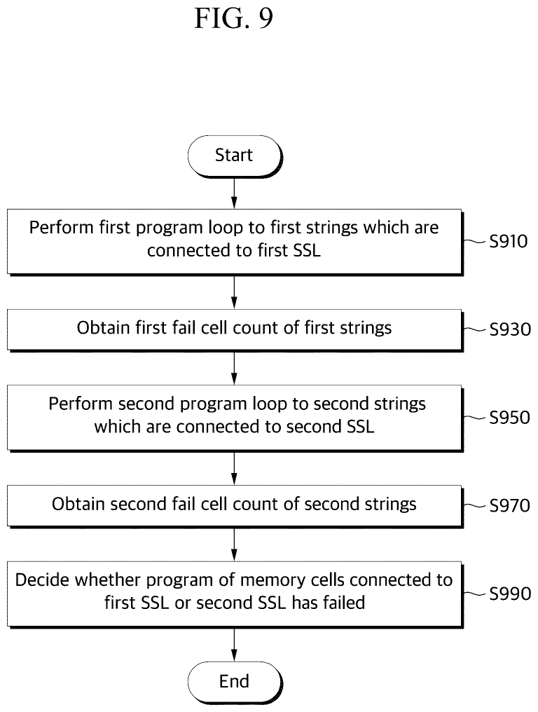

FIG. 9 is a flowchart illustrating a first loop error detection method of a memory apparatus according to example embodiments of the present disclosure.

Referring to FIG. 1 and FIG. 9, in operation S910, the memory apparatus 100 according to example embodiments may perform a first program loop to first strings connected to the first SSL. For instance, the memory apparatus 100 may perform the first program loop to the plurality of first strings which are connected to the first SSL and are in an erasure state. The erasure state signifies a state of not having been programmed due to having been initialized with respect to the plurality of first strings, and the first program loop may indicate trying a program loop once without trying the same by multiple times.

In operation S930, the memory apparatus 100 according to example embodiments may obtain a first fail cell count of the first strings. For instance, after performing a loop once, the memory apparatus 100 may identify memory cells which have not reached a verify voltage after performing a loop once as fail cells, and may accumulate or statistically process the number of fail cells by each string or SSL unit to obtain a fail cell count.

In operation S950, the memory apparatus 100 according to example embodiments may perform a second program loop to second strings connected to the second SSL, and, in operation S970, the memory apparatus 100 according to example embodiments may obtain a second fail cell count of the second strings. The memory apparatus 100 may obtain the second fail cell count which is the number of memory cells which have not reached a verify voltage by performing the second program loop under a premise that that the corresponding strings are initialized in the erasure state, and that the plurality of second strings connected to the second SSL which is different from the first SSL are selected.

In operation S990, the memory apparatus 100 according to example embodiments may decide whether a program of memory cells connected to the first SSL or the second SSL has failed. For instance, the memory apparatus 100 may decide, based on the first fail cell count and the second fail cell count, whether the program of the memory cells connected to the first SSL or the second SSL has failed.

For instance, the memory apparatus 100 may store the first parameter and the second parameter of the Min/Max pass loop register 164 in FIG. 2 as the first fail cell count, and may update a value of the first parameter and the second parameter which are stored based on the second fail cell count. The memory apparatus 100 may compare a difference between the value of the first parameter and the second parameter to the threshold value stored in the delta register 166 of FIG. 2 to determine whether the program of the memory cells connected to the first SSL or the second SSL has failed.

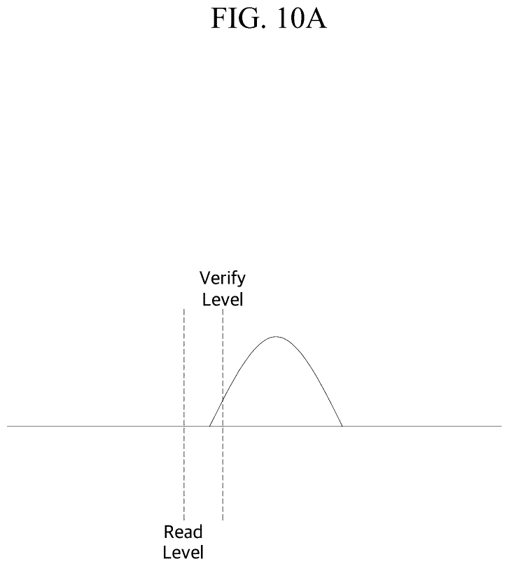

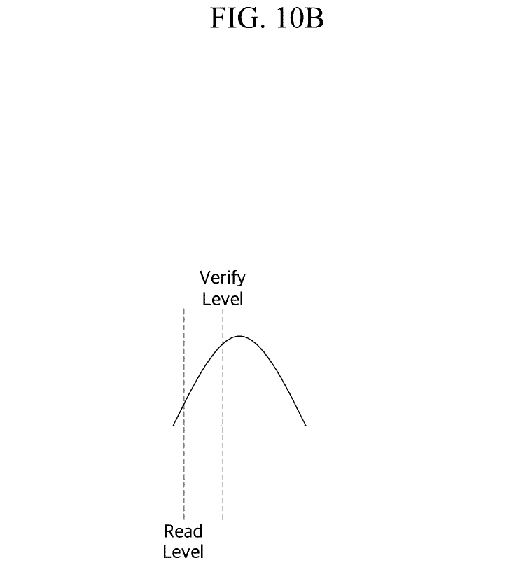

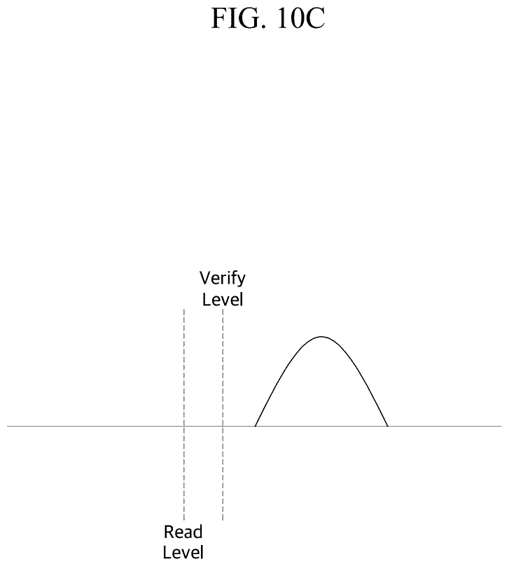

FIG. 10A, FIG. 10B and FIG. 10C are graphs illustrating a result of having performed a first loop program according to example embodiments of the present disclosure. In each graph, an x axis corresponds to a threshold voltage, and a y axis may indicate the number of pass memory cells or memory cell distribution at the threshold voltage.

Referring to FIG. 10A, the graph indicates a normal state in which threshold voltage distribution is stably formed between a read level and a verify level. In this case, because most of the memory cells satisfy a verify standard, and, at the same time, exceed a read standard, it may be decided that an error does not exist.

Referring to FIG. 10B, the graph indicates a case in which a plurality of cells with a low threshold voltage are included. In case that a program is slowly progressed, threshold voltage distribution is close to the read level, or some memory cells are located at a level less than the read level, and accordingly, the memory apparatus 100 may process memory cells connected to a corresponding SSL as a program failure or process the same as an error.

Referring to FIG. 10C, the graph indicates a case in which the threshold voltage has excessively increased. In this case, the entire distribution significantly exceeds the verify level, and some memory cells may be programmed at a high voltage. For instance, in case that the first loop program is performed in a word line, the same may be shorter than a normal loop due to a disturbance occurring due to a repeated read operation performed in another SSL of another adjacent word line or the corresponding word line. Accordingly, the memory apparatus 100 may process the memory cells connected to the corresponding SSL as a program failure or process the same as an error.

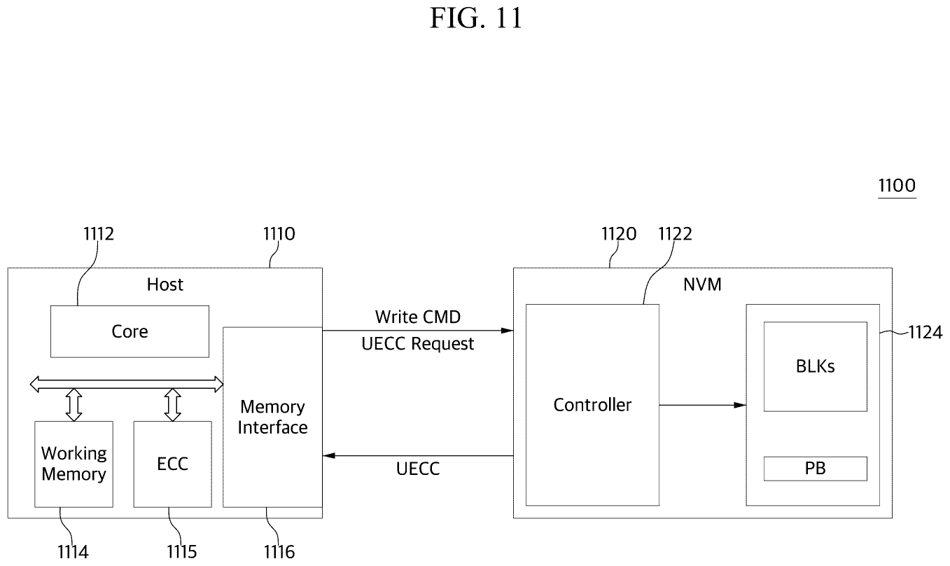

FIG. 11 is a block diagram illustrating a memory system according to example embodiments of the present disclosure.

Referring to FIG. 11, a memory system 1100 may include a host 1110 and a storage device 1120. The host 1110 may include a core 1112, a working memory 1114, an ECC block 1115 and a memory interface 1116. Here, the storage device 1120 may include a micro-controller 1122 and a memory device 1124. Here, the storage device 1120 may be provided as a perfect page new (PPN) memory device.

The core 1112 of the host 1110 may process various application programs or data which are loaded in the working memory 1114. Software such as an application program and an operating system may be loaded in the working memory 1114. In an operating system loaded in the working memory 1114, software modules performing re-programming of written data or mapping manipulation of a memory block by using a program state (PS) or a loop state (LS) of the present disclosure may be loaded.

The memory interface 1116 may change a memory address which is requested to be accessed by the core 1112 into a physical address. For instance, the memory interface 1116 may perform a function of a flash translation layer (FTL).

The storage device 1120 may include the micro-controller 1122 and the memory device 1124. The micro-controller 1122 may deliver a command (CMD), an address (ADD), control signals (CTRLs) and data provided from the host 1110 to the non-volatile memory device 1124. The storage device 1120 may determine and store UECC with respect to memory cells connected to a word line during an operation of a program. The storage device 1120 may return UECC detected in a word line to a host 310 in response to an UECC request from the host 1110.

As described above, example embodiments have been disclosed in the drawings and the specification. Although the example embodiments have been described using specific terminology in this specification, the same is used only for the purpose of describing the technical spirit of the present disclosure and is not used to limit the scope of the present disclosure as defined in the claims. Therefore, those of ordinary skill in the art will understand that various modifications and other equivalent example embodiments are possible therefrom.

What is claimed is:

1. An operation method of a memory apparatus, comprising:
programming a plurality of first memory cells connected to a first word line in strings connected to a first string select line (SSL);
obtaining a first pass loop count corresponding to a first program state of the plurality of first memory cells which are programmed;
programming a plurality of second memory cells connected to the first word line in a plurality of strings connected to a second SSL into the first program state;
obtaining a second pass loop count corresponding to the first program state of the plurality of second memory cells which are programmed into the first program state; and
deciding, based on the first pass loop count and the second pass loop count, whether a program of a plurality of memory cells connected to the first word line has failed.

2. The operation method of claim 1, wherein the deciding of whether the program has failed comprises:
setting the first pass loop count as a first parameter and a second parameter;
updating the first parameter and the second parameter based on the first parameter, the second parameter, and the second pass loop count; and
determining whether the program has failed based on the first parameter, the second parameter, and a pre-set threshold value.

3. The operation method of claim 2, wherein the updating comprises:
updating, in case that the second pass loop count is greater than the first parameter, the second pass loop count as the first parameter; and
updating, in case that the second pass loop count is smaller than the second parameter, the second pass loop count as the second parameter.

4. The operation method of claim 2, wherein the determining of whether the program has failed comprises:
determining that, in case that a difference between the updated first parameter and the updated second parameter is equal to or greater than the threshold value, the program of the plurality of memory cells connected to the first word line has failed.

5. The operation method of claim 2, wherein, in case that the plurality of first memory cells and the plurality of second memory cells are a quad-level cell (QLC), the first parameter and the second parameter are respectively updated as two pairs different from one another.

6. The operation method of claim 2, wherein the threshold value is set for each program state.

7. The operation method of claim 2, further comprising:
obtaining a second word line address; and
initializing the first parameter and the second parameter.

8. The operation method of claim 2, wherein the threshold value is set according to a number of erasures of the first word line.

9. The operation method of claim 2, wherein the plurality of first memory cells and the plurality of second memory cells comprise at least two of a single-level cell (SLC), a multi-level cell (MLC), a triple-level cell (TLC) and a QLC, and
wherein the threshold value is set to vary at the SLC, the MLC, the TLC and the QLC.

10. The operation method of claim 1, wherein the first SSL and the second SSL are adjacent to one another.

11. The operation method of claim 1, further comprising:
performing, in case that the program of the memory cells connected to the first word line is decided to have failed, a run-time bad block (RTBB) processing with respect to the first word line.

12. The operation method of claim 1, wherein the memory apparatus has a vertical not AND (VNAND) flash memory structure.

13. A memory apparatus comprising:
a cell array including a plurality of memory cells;
a row decoder connected to the cell array through a plurality of word lines and an SSL; and
a control logic circuit configured to control the row decoder,
wherein the control logic circuit is configured to:
program a plurality of first memory cells of the plurality of memory cells connected to a first word line in strings connected to a first SSL;
obtain a first pass loop count corresponding to a first program state of the plurality of first memory cells which are programmed;
program a plurality of second memory cells among the plurality of memory cells connected to the first word line in a plurality of strings connected to a second SSL into the first program state;
obtain a second pass loop count corresponding to the first program state of the plurality of second memory cells which are programmed into the first program state; and
decide, based on the first pass loop count and the second pass loop count, whether a program of the plurality of memory cells connected to the first word line has failed.

14. The memory apparatus of claim 13, wherein the control logic circuit comprises a register storing a first parameter and a second parameter, and is configured to:
store the first pass loop count in the register as the first parameter and the second parameter;
update the first parameter and the second parameter in the register based on the first parameter, the second parameter and the second pass loop count; and
determine whether the program has failed based on the first parameter, the second parameter, and a pre-set threshold value.

15. The memory apparatus of claim 14, wherein the control logic circuit is configured to:
update, in case that the second pass loop count is greater than the first parameter, the second pass loop count as the first parameter to store the updated second pass loop count in the register; and
update, in case that the second pass loop count is smaller than the second parameter, the second pass loop count as the second parameter to store the same.

16. The memory apparatus of claim 14, wherein the threshold value is set for each program state.

17. The memory apparatus of claim 14, wherein the control logic circuit is configured to:
obtain a second word line address; and
initialize the first parameter and the second parameter which are stored in the register.

18. The memory apparatus of claim 14, wherein the plurality of memory cells comprise at least two of an SLC, an MLC, a TLC, and a QLC, and
wherein the threshold value is set to vary at the SLC, the MLC, the TLC and the QLC.

19. An operation method of a memory apparatus, comprising:
performing a first program loop to a plurality of first strings which are connected to a first SSL and are in an erasure state;
obtaining a first fail cell count of the plurality of first strings;
performing a second program loop to a plurality of second strings which are connected to a second SSL and are in an erasure state;
obtaining a second fail cell count of the plurality of second strings; and
deciding, based on the first fail cell count and the second fail cell count, whether a program of a plurality of memory cells connected to the first SSL or the second SSL has failed.

20. The operation method of claim 19, wherein the deciding of whether the program has failed comprises:
setting the first fail cell count as a first parameter and a second parameter;
updating the first parameter and the second parameter based on the first parameter, the second parameter, and the second fail cell count; and
determining whether the program has failed based on the first parameter, the second parameter, and a pre-set threshold value.
